(19) United States
(12) Patent Application Publication
(10) Pub. No.: US 2026/0219881 A1
(43) Pub. Date: Jul. 30, 2026

(54) A DIGITAL SIGNAL PROCESSOR FOR STREAMING AUDIO APPLICATIONS

(71) Applicant: Axign B.V., Enschede (NL)

(72) Inventor: Daniel SCHINKEL, Enschede (NL)

(21) Appl. No.: 19/142,015

(22) PCT Filed: Dec. 1, 2023
(86) PCT No.: PCT/NL2023/050631

§ 371 Date: Jun. 20, 2025

(30) Foreign Application Priority Data
Dec. 21, 2022 (NL) 2033790

(51) Int. Cl. G06F 9/22; G06F 3/16; G06F 9/30; H03K 7/08

(52) U.S. Cl. CPC G06F 9/226; G06F 3/165; G06F 9/30098; H03K 7/08

(57) ABSTRACT

The present invention is in the field of basic electronic circuitry, in particular of a digital signal processor for streaming audio applications, an audio reproduction signal path comprising the Digital Signal Processor (DSP) for streaming, an integrated circuit comprising said digital signal processor, and a device comprising said digital signal processor or said integrated circuit.

### FIELD OF THE INVENTION

The present invention is in the field of basic electronic circuitry, in particular of a digital signal processor for streaming audio applications, an audio reproduction signal path comprising the Digital Signal Processor (DSP) for streaming, an integrated circuit comprising said digital signal processor, and a device comprising said digital signal processor or said integrated circuit.

### BACKGROUND OF THE INVENTION

An audio power amplifier comprises basic electronic circuitry that amplifies low-power electronic audio signals that enter the circuitry, to a high enough power for driving a loudspeaker. Audio power amplifiers find many applications. The audio amplifier may be combined in a chain of electronic components or electronic circuits, each performing an individual task or contributing to a common task. Basically, any audio signal can be provided to the power amplifier, as is commonly done. The output signal of the audio amplifier power may be from a few watts to tens or hundreds of watts, and sometimes even a multitude thereof. Power amplifiers are typically integrated in a (final) product or integrated circuit.

Design parameters for audio power amplifiers are amongst others frequency response, gain, noise, and distortion, which parameters are typically interdependent.

A Class-D amplifier is typically used in modern consumer electronics audio products, bass amplifiers and sound reinforcement system gear. Amplifiers may comprise filters, preamplifiers, power output stages and the like. An audio filter is typically a frequency dependent circuit. It is designed to operate in a specific audio frequency range. It is noted that a human hearing range is commonly considered to run from 20 to 20,000 Hz. There is however a considerable variation between individuals, especially at high frequencies. Also, typically there is a gradual loss of sensitivity to higher frequencies with age. In addition, sensitivity to specific frequencies may also vary with said frequency. The audio frequency range typically used in audio amplifiers therefore runs from about 20 Hz to 20 kHz, and sometimes to 40 kHz or even 100 kHz. Audio filters are designed to amplify, pass, or attenuate specific frequency ranges. Many types of filters exist, for instance low-pass filters, high-pass filters, band pass filters, all-pass filters effecting a phase of a given frequency component, etc.

The last few years have seen a significant increase in the amount of digital signal processing used in personal audio devices. Next to more traditional applications, such as interpolation and decimation filters, new applications, such as Active noise control (ANC), require the signal processing to operate at high sample rates. Power efficiency of such processing is a big challenge, especially for small devices, such as ‘true wireless earbuds’. Although a traditional Digital Signal Processor (DSP) is already optimized for signal processing, it is typically far from optimal for efficient high-frequent processing. Such general-purpose processors are more geared towards complex algorithms at lower sample-rates (such as compression, voice-detection, etc.), which require significant amounts of program and data memory and control. It was shown that the power involved in the control and memory access tends to be much larger than the power for the core processing operations, so power consumption is an issue. The power efficiency challenge has prompted the use of dedicated hardware for the high-speed ANC filters in prior audio IC implementations (e.g., the [ADAU1788]), with the drawback that this hardware is very application specific.

Incidentally reference can be made to U.S. Pat. No. 6,081,783 A, US 2005/144210 A1, and US 2019/065188 A1. U.S. Pat. No. 6,081,783 A recites an audio decoder for operating on a received compressed audio data stream compressed using an algorithm employing transform encoding and a bit allocation routine. A first processor performs a first set of operations on the received compressed audio data stream including parsing the compressed audio data stream, recovering data fields within the compressed audio data stream, calculating a bit allocation, and passing frequency domain coefficients to shared memory. A second digital signal processor performs a second set of operations on data passed from the first digital signal processor to shared memory including performing inverse transform operations on the data passed from the first digital signal processor. US 2005/144210 A1 recites a programmable logic device (PLD) with columns of DSP slices that can be cascaded to create DSP circuits of varying size and complexity. Each slice includes a mode port that receives mode control signals for dynamically altering the function and connectivity of related slices. Such alterations can occur with or without reconfiguring the PLD. US 2019/065188 A1 recites an accelerated processor structure on a programmable integrated circuit device includes a processor and a plurality of configurable digital signal processors (DSPs). Each configurable DSP includes a circuit block, which in turn includes a plurality of multipliers. The accelerated processor structure further includes a first bus to transfer data from the processor to the configurable DSPs, and a second bus to transfer data from the configurable DSPs to the processor.

It is an objective of the present invention to overcome disadvantages of the prior art digital signal processor and amplifier without jeopardizing functionality and advantages.

### SUMMARY OF THE INVENTION

A compact digital signal processor (mμDSP) is provided, that is highly optimized for low-power processing of streaming audio signals. It typically uses very small memories (e.g. 256 words), a wide program memory with simple encoding of multiple sub-instructions, and a data path, with a redundant data-format and without implicit pipelining. The presented micro-DSP (mμDSP) takes a middle ground between a dedicated hardware and general purpose DSP implementation. It aims to be both power efficient and still enable a range of streaming audio applications. A feature of the present invention is that it may keep processing very local, with both a compact processing pipeline and very small memories (sometimes referred to as a high ‘data locality’). For more complex tasks (or a cascade of tasks), multiple mμDSPs can be interconnected to each other, either directly, or through a Network on a Chip (NoC) or the like for more flexibility.

It is noted that the present mμDSP has been built from the ground up, using a combination of techniques typically used in dedicated hardware implementations, as well as some building blocks from processor architectures. Below, various aspects of the architecture definition and design are listed. For more background information reference is also made to the figures. The dedicated hardware implementations, without the prior art overhead, can be two orders of magnitude more efficient than a general purpose DSP, which in itself can again be an order of magnitude more efficient than a normal CPU. So a huge improvement in this respect is made.

In an overview of the present invention the following is noted. At a top-level perspective:
The mμDSP is in particular designed for power-efficient streaming signal processing (especially oversampled audio), typically using simple algorithms with low data memory footprint per DSP.
The memory in the mμDSPs is highly local, single cycle accessible, and dedicated for that particular mμDSP.
More complex tasks (or better yet: a cascade of tasks) can be distributed over multiple mμDSPs. The mμDSPs have multiple input and output ports to facilitate direct interconnection, or connect via a low-overhead circuit-switched NoC.
   The input ports write directly into the mμDSPs local X-memory memory (which is replicated as many times as there are input ports).
   The input port writing is a standalone process, and does not require any mμDSP cycles. When a mμDSP and an input port both want to access the same memory at the same time, the mμDSP is typically stalled unless it claims priority with a special instruction flag.
      The mμDSP is event-driven, in that a program starts up whenever a certain condition occurs, the program then processes the relevant data and subsequently goes back to a low-power idle state. Small blocks of dedicated hardware (such as counters and bound checks on memory pointers) are used to detect the events. The following is an example thereof:

### Start Address Events (in Order of Priority)

0 Program after reset
1 X0 invalid frame trigger (received EOF of invalid frame))
2 X1 invalid frame trigger (received EOF of invalid frame))
3 X0 buffer (nearly) full (WX0-BX0>BWF0)
4 X1 buffer (nearly) full (WX1-BX1> BWF1)
5 X0 buffer (nearly) empty (WX0-BX0<BWE0)
6 X1 buffer (nearly) empty (WX1-BX1<BWE1)
7 X0 frame trigger (received EOF of valid frame)
8 X1 frame trigger (received EOF of valid frame)
9 NI0 output requests sample
10 NI1 output requests sample
11 Counter event (counter passes zero)

An exemplary embodiment has at least one of the following event categories (in order of priority):
Startup event (program executed when the mμDSP comes out of reset)
Invalid input fame events (triggered by an invalid-end-of-frame input signal)
Buffer full events (triggered by memory pointers crossing a programmable threshold)
Buffer empty events (triggered by memory pointers crossing a programmable threshold)
Input frame events (trigged by an end-of-frame input signal)
Counter event (triggered when an internal programmable counter passes through zero)

In view of program and control:
Besides small data-memory, the mμDSPs also have much smaller program memory (typically 256 words in the first embodiment) than is typical in prior art DSPS.
The mμDSP can execute many sub-operations in parallel, a bit similar to Explicit parallel instruction computing (EPIC) or Very Long Instruction Word (VLIW) instruction set architectures, but then at a very simple level.
To enable simple encoding of the sub-operations, the program memory is very wide (such as 96 bits in an embodiment) and contains separate fields for e.g. the address generators, Instruction control and the various parts of the data paths, with a total of 32 fields in the current embodiment.

The simple encoding of the sub-operations into the program memory also means that no pipeline cycle is needed for the instruction decode. For additional efficiency, a local latch bank may be used in which the 4 last instructions are stored. Activation of a local-loop instruction turns of the main memory and iterates N-times over these 1-4 instructions. Each instruction takes only 1 cycle, so the programs in the mμDSP can run very fast and with a very predictable run time.

Conditional execution and branching are both supported. The condition typically is determined by the state of a flag which value depends on the results in the data path. Conditional execution (including a conditional execution of a jump) is possible with a dedicated ‘conditional execute’ sub-field in the opcode. Datapath: The data path of the mμDSP typically is replicated M times (as many times as there are input ports and XMEM's): Each data path can be used individually, but they can also act as one data path with M-times the word length per data path. This increases the flexibility of the processing of various word-lengths. In an exemplary embodiment, the data path length is 32 bits and M=2, so 64 bits signals can be processed. Each data path is divided into groups of 8 bits and a mask setting can select how many of the 8 bits groups create a word, to further increase the flexibility of the word-lengths. The data path implements a mini-floating point multiplication (with an 8-bits significand and 5 bits exponent). Such a mini-floating point turns out to have enough precision to be used as coefficient in IIR filters. Where more precision is needed, multiple iterations can give arbitrary precision. The mini-floating point multiplication is composed of a barrel-shifter that is replicated four times for the least significant bits and which work together with the four partial products of a Modified Booth-encoded multiplier. An accumulator (with accumulation register A) is added after the floating point multiplier. The accumulator has a second input that can either be the accumulation register (to implement a MAC operation), or one of the other data path registers (X, Y, Z). With its two inputs, the accumulator can perform arithmetic add/subtract operations as well as a variety of logic operations for bit-manipulations. There is no hidden pipelining. There is only a minimal pipelining between accessible registers in the data path. This serves the following purposes: Many signal processing algorithms are recursive and need previously calculated results as input for the next calculations, so such results should be available as soon as possible (without having to wait for the pipeline). It is desired to avoid spending power and complexity in pipeline flushing when conditional instructions are carried out. Note that such pipeline flushing options are very possible in possible future embodiments, when speed is more important than efficiency. To still enable accumulation of 2*32-bits results without pipelining, a redundant data-format is used that adds one additional ‘guard’ bit to every group of 8 bits, effectively encoding a 9-bits signed digit (2s complement). The 1 bit overlap between the groups (1-bit redundancy) is used to break the carry propagations in such a way that the longest carry chain becomes about 12 bits (because the multiple partial products and accumulator give some word-length increase from 9 to 12 bits when added together).

Parametric design: The whole mμDSP is generated programmatically with e.g. the number of input ports (and consequently the number of X-memories and data paths) as parameters. This enable simple generation of variations with different number of ports or with different memory sizes or different digit-sizes.

As discussed above, the architecture of the mμDSP as a whole is different from prior art because of the focus on power efficiency and simplicity. However, within the mμDSP, a few parts can be pinpointed that are most different from prior art, warranting separate claims or separate applications:

The use of a small latch-bank for high-efficient local loops; the data path with signed-digits with 1-bit guards per digit and flexible word-length. The floating-point multiplier that combines a barrel-shifter with the booth-multiplication

Typically an instruction decoder is absent. The present DSP provides a simple input-output behaviour with input ports writing directly into memory.

The most direct application of the invention is for the processing of oversampled audio signals. Such oversampled signals are typically used in (sigma-delta) data converters and digital amplifiers, such as Axign's audio controller [U.S. Pat. No. 10,659,028]. Oversampled signals are also used in Active Noise Reduction loops, mainly because down-sampling of the microphone's digitized (bitstream) output would incur too much delay. To suit the above applications, the DSP is optimized for high-speed FIR and IIR filtering (it can compute a biquad filter stage in 3 cycles).

For more general audio applications, during the development of the mμDSP it was made sure that the μDSP was well suited for the following categories of algorithms:
Channel mixing and volume control
FIR/IIR filters (for sound processing, interpolation, decimation & ANC)
Adaptive filters/algorithms (LMS)
Polynomial function evaluation (for ASRC & nonlinear compensation)
Signal statistics (mean-square, correlation, etc.)
Frequency domain analysis (FFT)
Auxiliary processing (division for normalization, SQRT for RMS, CORDIC for sin/cos, etc.)

The μDSP can also be applied for other one-dimensional signals, for example for high-speed control loops or data-communication.

The present invention relates in a first aspect to Digital Signal Processor (DSP) for streaming an audio application (1), in particular a low power DSprocessor, comprising two or more micro digital signal processors (μDSPs), in particular 3-12 μDSPs, more in particular 4-8 μDSPs, wherein the at least two or more μDSP's form a network, wherein each individual μDSP comprises a local memory with a size <2¹⁸ words, in particular <2¹⁶ words, more in particular <2¹⁴ words, wherein each individual word has a size of 256 bits or smaller, in particular 128 bits or smaller, more in particular 96 bits or smaller, such as 32 bits or smaller, wherein the two or more μDSPs are connected or connectable in series and/or in parallel, wherein the two or more micro digital signal processors (μDSPs) each individually are configured to receive an input signal selected from an audio source input signal, and to receive an input signal of another of the two or more micro digital signal processors (μDSPs), and wherein the two or more micro digital signal processors (μDSPs) each individually are configured to provide an output signal selected from an output signal to a digital to analogue converter, and an output signal to another of the two or more micro digital signal processors (μDSPs), wherein the two or more micro digital signal processors (μDSPs) each individually comprise two or more μDSP data interface inputs, wherein each micro digital signal processor is configured to operate at a clock frequency of >1 MHz, in particular at a clock frequency of >10 MHz, more in particular at a clock frequency of ≥20 MHz, even more in particular at a clock frequency of >100 MHz, such as >200 MHz. [see e.g. FIG. 1].

In a second aspect the present invention relates to an audio reproduction signal path comprising the Digital Signal Processor (DSP) for streaming an audio application (1) according to the invention, in particular further comprising at least one element selected from a loop filter, wherein the loop filter is configured to receive input from at least one of a micro DSP, a butterfly mixer, wherein the butterfly mixer is configured to receive input from at least one loop filter, to mix said loop filter input, and to provide output to at least one PWM, a PWM, wherein the PWM is configured to receive input from the loop filter and/or the butterfly mixer, to pulse width modulate said input, and to provide output to an output crossbar or to an output channel, an output crossbar, an output, a low latency ADC configured to provide output to an output or output crossbar and to receive input from a μDSP, a router, the router configure to receive input from at least one further element and to provide output to at least one further element, a feedback loop filter, wherein the feedback loop filter is configured to provide output to a digital analogue converter, in particular a Sigma-Delta DAC, and configured to provide input to at least one of the two or more micro digital signal processors (μDSPs), and a decimator configured to receive input from a Low Latency Analog to Digital Converter (LLADC) and to provide output toa μDSP [see e.g. FIG. 1].

In a third aspect the present invention relates to an integrated circuit comprising the Digital Signal Processor (DSP) for streaming an audio application according to any of the preceding claims.

In a fourth aspect the present invention relates to an electronic device comprising an integrated circuit according to the invention or a Digital Signal Processor according to the invention, such as an audio amplifier, an active loudspeaker system, an active noise reduction system, a high-speed closed loop controller, a high resolution low latency data converter, an analogue to digital (A/D) converter, a power supply controller, a motor controller, a digital audio converter, a digital amplifier con-troller, and combinations thereof.

Thereby the present invention provides a solution to one or more of the above mentioned problems.

Advantages of the present description are detailed throughout the description.

### DETAILED DESCRIPTION OF THE INVENTION

The present invention relates in a first aspect to a Digital Signal Processor (DSP) for streaming an audio application according to claim 1.

In an exemplary embodiment of the present DSP each individual micro digital signal processor (μDSP) comprises a control interface configured to process input from an external source such as a host processor, where this input is used to write or read the contents of the program-memory (PMEM) and/or coefficient memory (YMEM) and thereby control the behaviour of the μDSP and/or read out status information. [FIG. 2].

In an exemplary embodiment of the present DSP the two or more micro digital signal processors (μDSPs) each individually comprise two or more μDSP data interface inputs, and/or two or more DSP data interface outputs. The data interface inputs write their data directly into the data memory (XMEM). The data interface outputs receiver their data from output data registers [FIG. 2].

In an exemplary embodiment of the present DSP the at least two or more μDSP's form a network, in particular a switchable network, wherein the network comprises an array n*m of μDSP routers(i,j), wherein i∈[1,n] and j∈[1,m], in particular wherein n is in the range of 2-2⁸, in particular wherein m is in the range of 2²-2⁸, more in particular wherein n is in the range of 2²-2⁷, in particular wherein m is in the range of 2²-2⁷, even more in particular wherein n is in the range of 2³-2⁶, in particular wherein m is in the range of 2³-2⁶, wherein each individual router(i,j) comprises data inputs and outputs for the μDSP and also comprises at least two router inputs and at least two router outputs for connecting to a router(i,j) selected from a router (i+1,j) a router(i,j+1), a router(i,j−1), and a router (i−1,j). [FIG. 4]

In an exemplary embodiment the present DSP comprises at least one 32 bit μDSP, in particular at least three 32 bit μDSPs, and at least one 96 bit μDSP.

In an exemplary embodiment of the present DSP the at least one 96 bit μDSP comprises three 32 bit sub-memories. [FIG. 9]

In an exemplary embodiment of the present DSP the at least two μDSPs or the network of the at least two μDSPs are/is configured to receive multiple inputs, in particular wherein inputs are selected from pulse width modulator input, loop filter input, Analog to Digital Converter (ADC) input, in particular Low-Latency ADC (LLADC) input, bitstream inputs such as Direct Stream Digital (DSD) or digital microphone (DMIC) inputs, Micro Controller (MCU) input, routing input, and Serial Audio Port (SAP) input, and/or wherein the at least two μDSPs or the network of the at least two μDSPs are/is configured to provide multiple outputs, in particular wherein outputs are selected from pulse width modulator output, loop filter output, ADC output, in particular low-latency ADC output, DSD output, DMIC output, MCU output, routing output, and SAP output. [FIG. 5]

In an exemplary embodiment of the present DSP the at least two μDSPs each individually are configured to mark frame input with a unique identifier in the form of an additional bit next to the data input to mark the end of a frame of data words.

In an exemplary embodiment of the present DSP the at least two μDSPs each individually are configured to be event driven, in particular wherein the external events are selected from a reset, an output request sample, an invalid frame and a (valid/normal) frame event and where the internal events are selected from in particular a buffer full condition, a buffer empty condition and a counter event. Once triggered, the program that belongs to an event will run to completion and can not be interrupted by another event. An event is therefore considered different from an ‘interrupt’ as is known from prior art is considered different from an event according to the present invention. Handling of interrupts typically require additional overhead in control and memory to store the state of the main program before the interrupt and recover the state afterwards. Such overhead is considered a significant drawback.

In an exemplary embodiment of the present DSP each individual μDSP is configured to process data over a data path, wherein processing is configured to be controlled by a program controller, wherein the controller is configured to control at least one of receiving input from the local data registers, to provide a mask over the received input, in particular a 32-64 bit mask, to rotate the masked input, to multiply the rotated input, to perform arithmetic operations on the rotated input and/or on the local data registers input (In computing, an arithmetic logic unit (ALU) is a combinational digital circuit that performs arithmetic and bitwise operations on integer binary numbers), to provide a flag on the arithmetic output, to provide a guard on the arithmetic output, to clip overflow, and to provide output to a local data registers [FIG. 6].

In an exemplary embodiment of the present DSP the at least two μDSPs each individually are configured to comprise in an accumulator one guard bit per eight word bits, wherein the guard bit is the first or the last bit of the eight bits of the word. [FIG. 8]

In an exemplary embodiment of the present audio reproduction signal path, the one or multiple μDSPs (400) provide input to a programmable pulse width modulating (PWM) controller (1), where the DSPs are used for interpolation of a PCM input signal, decimation of a loop-filter output signal, audio processing and filtering and/or adapting the behaviour of loop-filters (20). The PWM controller comprises in series (i) at least two parallel loop filters (20) for loop-gain and signal processing, preferably at least four loop filters, each loop filter comprising multiple inputs (10, 15) and at least one output (25), wherein a loop filter (20) is adapted to receive PCM inputs from the DSP, perform common mode control, differential mode control and LC compensation, characterized in that each single output (25) being in electrical connection with (ii) at least one butterfly mixer (30), the butterfly mixer being capable of mixing at least two inputs (25) and of providing at least two mixed outputs (35) to (ii) at least two parallel pulse width modulators (PWM's) (40), wherein (iv) loop filters, butterfly mixer, and PWM's are individually and independently programmable and adaptable, wherein loop filter input (15) is adapted to receive at least one of a local digital PWM processed output signal (45), and an ADC output, and comprising at least one setting data storage means (440) for loading, adapting and storing programmable and adaptable settings, which can be accessed by the μDSPs [FIG. 12].

In an exemplary embodiment the present DSP comprises at least one local latch-buffer store configured for performing a local loop, at least one local program counter (PCL) for driving 32-bits output to a data register and for driving output from a local address register, wherein the PCL is configured to drive output to an n^{th} local address register and to drive output from an n+1th local address register, the at least one local latch-buffer store comprising four local address registers. [FIG. 9]

In an exemplary embodiment of the present DSP the local latched buffer store is configured to receive the program data (PDATA), a bundle of signals grouped in fields, where each field encode a sub-operation (in a binary ‘opcode’) and all sub-operations can execute in parallel. In an exemplary embodiment, the fields are the following:

| opcode field name | field descriptions | field bits |
|---|---|---|
| pm_cond | Conditional execution selection | pdata(95 downto 95) |
| pm_PC | Program counter control | pdata(94 downto 91) |
| pm_YRM | Y-register and YMEM load control | pdata(90 downto 87) |
| pm_MY | MY address pointer update control | pdata(86 downto 84) |
| pm_XRM0 | X-register and XMEM load control | pdata(83 downto 81) |
| pm_XRM1 | X-register and XMEM load control | pdata(80 downto 78) |
| pm_NIin | Network interface input control | pdata(77 downto 75) |
| pm_NI0out | Network interface output control | pdata(74 downto 73) |
| pm_NI1out | Network interface output control | pdata(72 downto 71) |
| pm_BX0 | BX address pointer update control | pdata(70 downto 69) |
| pm_BX1 | BX address pointer update control | pdata(68 downto 67) |
| pm_MX0 | MX address pointer update control | pdata(66 downto 63) |
| pm_MX1 | MX address pointer update control | pdata(62 downto 59) |
| pm_AuxL | Load control for auxiliary registers | pdata(58 downto 54) |
| pm_Mins | Multiplicant input selection | pdata(53 downto 52) |
| pm_MMsk | Multiplicant input mask | pdata(51 downto 47) |
| | (MMin<i> = Min AND Inmsk<i>) | |
| pm_ME | Multiplier/exponent source register selection | pdata(46 downto 44) |
| pm_Exp0 | Barrel-shifter (Exp0) control | pdata(43 downto 40) |
| pm_Exp1 | Barrel-shifter (Exp1) control | pdata(39 downto 36) |
| pm_ALU0in | ALU0 input selection | pdata(35 downto 33) |
| pm_ALU1in | ALU1 input selection | pdata(32 downto 30) |
| pm_ALU0 | ALU0 function selection | pdata(29 downto 28) |
| pm_ALU1 | ALU1 function selection | pdata(27 downto 26) |
| pm_ML0 | multiplier value and type/ | pdata(25 downto 23) |
| | logic function selection | |
| pm_ML1 | multiplier value and type/ | pdata(22 downto 20) |
| | logic function selection | |
| pm_loadA0 | Load A0 register with ALU0 output | pdata(19 downto 19) |
| pm_loadA1 | Load A1 register with ALU1 output | pdata(18 downto 18) |
| pm_flag | Flag behaviour selection | pdata(17 downto 14) |
| pm_loadZ0 | Z-register load control and | pdata(13 downto 11) |
| | A−>Z processing selection | |
| pm_loadZ1 | Z-register load control and | pdata(10 downto 8) |
| | A−>Z processing selection | |
| pm_IM | Immediate field in program memory | pdata(7 downto 0) |

Example of pm_XRM0 Op-Code:

| value | mnemonic | string | description |
|---|---|---|---|
| 0 | noload | | Do nothing to XMEM0/X0 |
| 1 | X0tM0 | XMEM0 = X0 | Store X0 to XMEM0(MX0) |
| 2 | X1tM0 | XMEM0 = X1 | Store X1 to XMEM0(MX0) |
| 3 | Z0tM0 | XMEM0 = Z0 | Store Z0 to XMEM0(MX0) |
| 4 | Z1tM0 | XMEM0 = Z1 | Store Z1 to XMEM0(MX0) |
| 5 | M0tX0 | X0 = XMEM0 | Load X0 from XMEM0(MX0) |
| 6 | X1tX0 | X0 = X1 | Load X0 from X1 |
| 7 | Y0tX0 | X0 = Y0 | Load X0 from Y0 |

Example of pm_BX0 Op-Code:

| value | mnemonic | string | description |
|---|---|---|---|
| 0 | nochange | | No change in the |
| | | | BX0 base pointer |
| 1 | incBX0 | BX0 = BX0 + 1 | Increment BX0 |
| 2 | BX0pIM | BX0 = BX0 + IM | Add Immediate to BX0 |
| 3 | BX0pMNX0 | BX0 = BX0 + MNX0 | Add MNX0 to BX0 |

The invention although described in detailed explanatory context may be best understood in conjunction with the accompanying examples and figures.

### SUMMARY OF FIGURES

FIG. 1-12 show details of the present digital signal processor and aspects thereof.

### DETAILED DESCRIPTION OF FIGURES

The figures are of an exemplary nature. Elements of the figures may be combined.

In the figures:
1 Digital Signal Processor
2 micro digital signal processor
3 local memory
3a program memory
3b coefficient memory
3c sub-memory
4 control interface
5 data interface
5a data interface input
5b data interface output
6 μDSP-network
6a network router
6b router input
6c router output
7 data path
8 guard bit
10 PCM signals
15 Bitstream signals from LLADC/PWM
20 Loopfilters
25 output signal loop filter
30 Butterfly mixer
31 (identical) butterfly element
35 output signal butterfly mixer/PWM input
40 pulse width modulator (PWM)
45 PWM output signal
50 crossbar
55 controller output signals
100 (digital) controller
200 integrated circuit
300 analog to digital converter (ADC)
305 differential mode ADC outputs
310 common mode ADC outputs
315 analog ADC inputs
400 (optional) digital signal processor (DSP)
405 serial interface input
410 serial digital data interface
415 serial interface output
420 clock generation unit
430 control interface
435 control interface output
440 control/settings registers
445 control register outputs
450 optional pre-filter for the feedback signals (15)
500 simple decimation filter (1st stage decimator)
505 decimation filter output

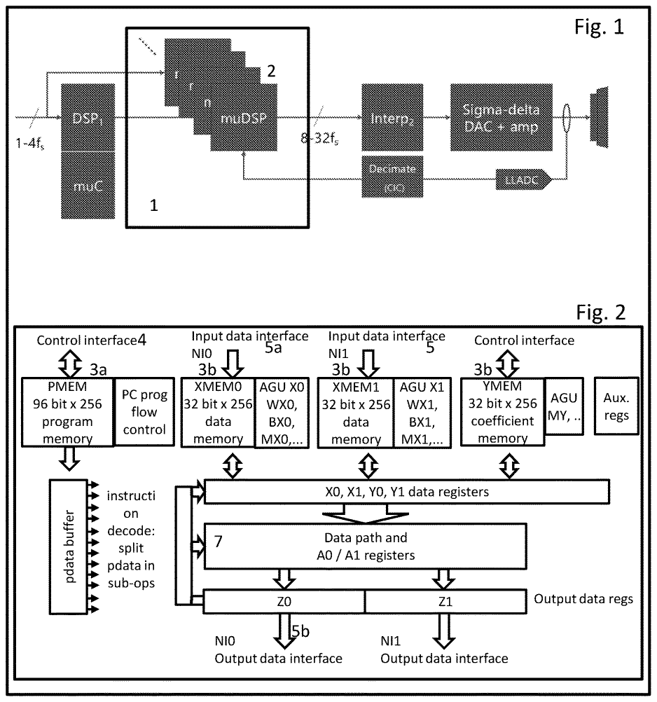

FIG. 1 shows a schematic layout of an audio signal path, comprising a first DSP and optional micro-controller, follow by the present micro-DSPs, and a feedback loop, as well as an audio output, such as a speaker or the like.

FIG. 2 shows a block schematic of the μDSP, in an exemplary configuration with a 96-bit×256 words instruction memory (PMEM) with its address generated by the program controller (PC) and a secondary buffer that stores the data of the latest instructions (PDATA) for re-use with local loops, two 32 bit data input and output interfaces, two 32 bit×256 words data-memories (XMEM0, XMEM1) with their address generating units (AGU) and a coefficient memory (YMEM) also with its own AGU. The XMEMs and YMEM interface with the data path registers (X0, X1, Y0, Y1, Z0, Z1). The data path itself also has accumulator registers A0, A1.

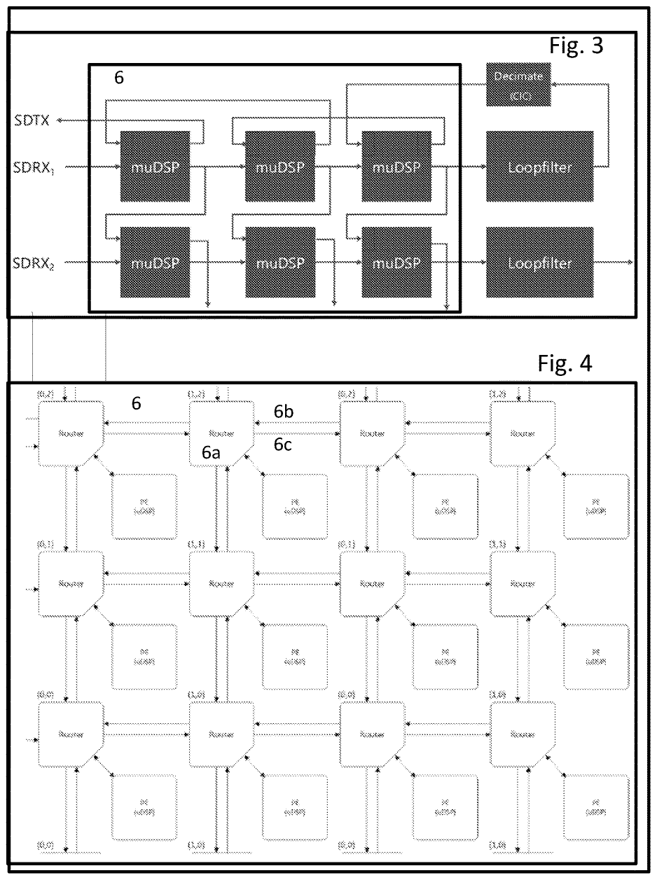

FIG. 3 shows an exemplary use of multiple μDSPs in a direct connection with each other, where μDSPs with two inputs and outputs are used to enable streaming audio applications with audio streams traveling in the left-to-right, right-to-left and top-to-bottom directions.

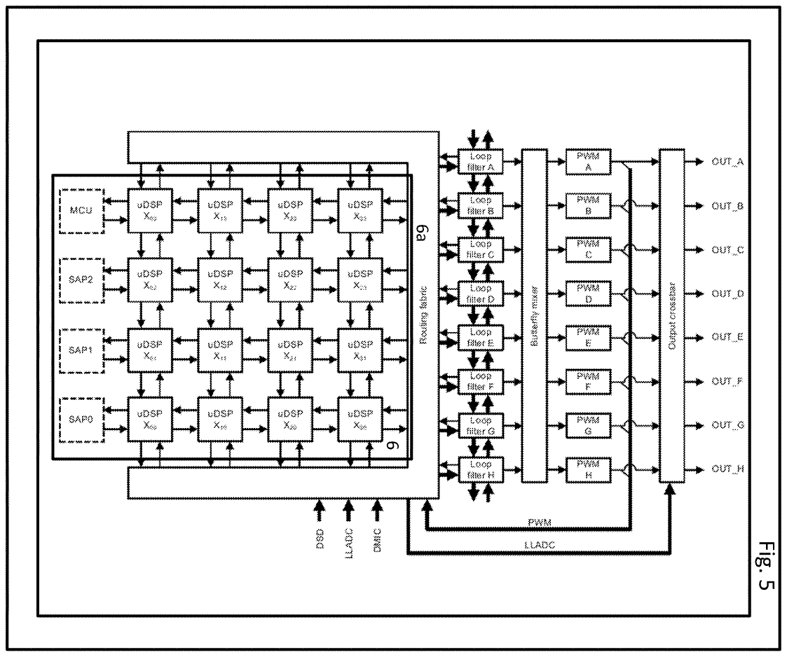

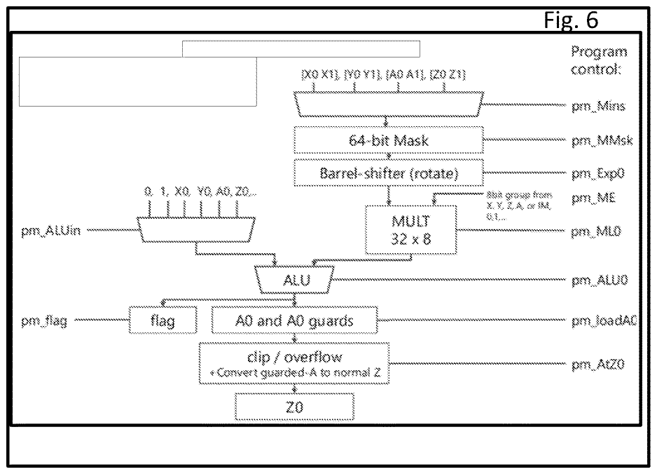

FIG. 4 shows an exemplary use of multiple μDSPs, connected via a network with configurable routers, to enable more versatility in the directions of the data streams. FIG. 5 shows an exemplary use of a network of multiple μDSPs in a digital audio controller, where the network connects the μDSPs not only to each other, but also to a variety of signal sources and signal destinations. The sources include PCM signals coming from an MCU, Serial Audio Ports (SAP) or bitstream sources such as a Direct-Stream-Digital (DSD) input or a Digital microphone (DMIC) input, or locally generated bitstream sources coming from Pulse-width-modulators (PWM), or (Low-Latency) ADCs. The signal destinations include loop-filters that further process the PCM signals from the μDSPs, typically at a higher sample-frequency to enable high-speed control-loops. The loop-filter outputs can be mixed with each other with butterfly mixers before being used as inputs for the PWMs. The outputs of the PWMs can be re-used as inputs or used as controller outputs via a configurable crossbar.

FIG. 6 shows a block-schematic of one of the data paths of the μDSP, with the dataflow from top to bottom. Starting at the top-right, different data registers can be selected as inputs for a mask, with the masking selectively passing or blocking groups of 8-bits. A barrel-shifter shifts/rotates the masked data and passes 32 bit of the shifted data to the multiplier. The other input of the multiplier is an 8-bit group, selected from a variety of constants or parts of the data-registers. The multiplier output is fed to the arithmetic-logic-unit (ALU) which combines the signal with a secondary input on the left, which is again a variety of constants or registers. The ALU output is stored into the accumulator registers A0, including a number of guard bits. A single-bit flag-register is also present that can be configured to signal a variety of conditions (such as larger-than-zero, smaller-than-zero, zero) of the ALU output or other data-registers. The guarded signals in the accumulator are subsequently converted to a normal binary form (using either clipping or overflow mechanisms) before they are stored in the data-paths output registers Z0.

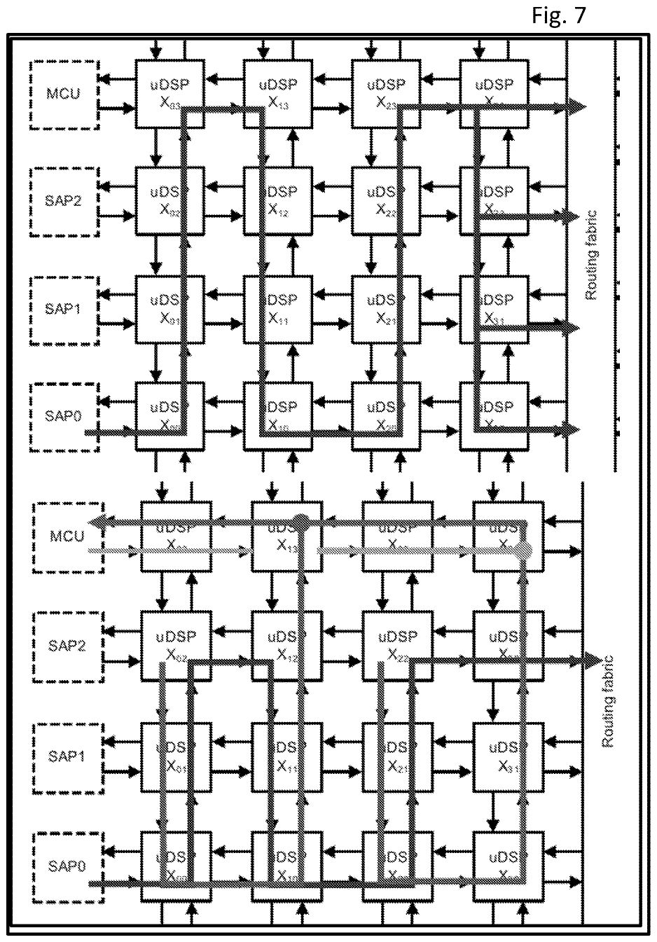

FIG. 7 shows exemplary data-streams for two exemplary configurations of the network of μDSPs.

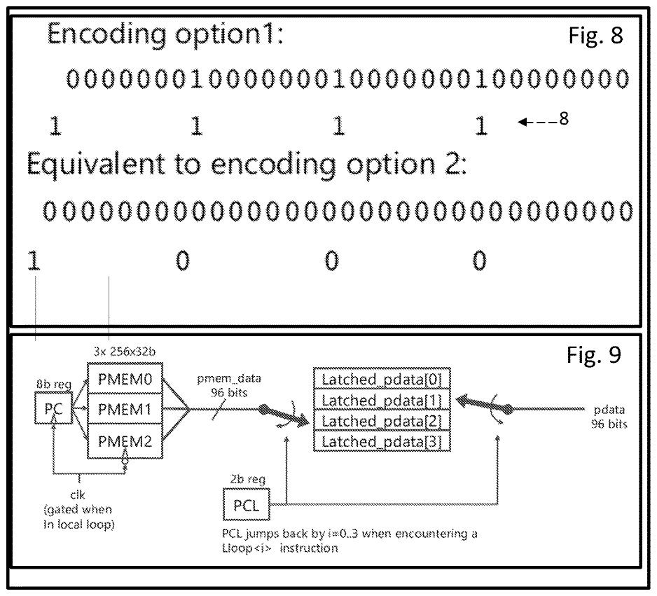

FIG. 8 shows the use of one guard-bit per 8-bit group in the accumulator register, where the guard bit functions as a sign-bit, creating signed digits of 9-bit each with one bit overlap between the digits. The overlap creates redundancy that can be leveraged to break the carry propagation. The redundancy makes that the same 32 bits value can be encoded in multiple ways as visible in the figure.

FIG. 9 shows the use of a local circular buffer to store the last N PDATA words, corresponding to the last N instructions. In the exemplary configuration of the μDSP, this is a buffer of latches with N=4. When the current instruction signals the start of a local loop, the main PMEM memory is disabled to stop its power consumption and only the local buffer is used for the looped instructions (so a local-loop is limited to cover at most N instructions).

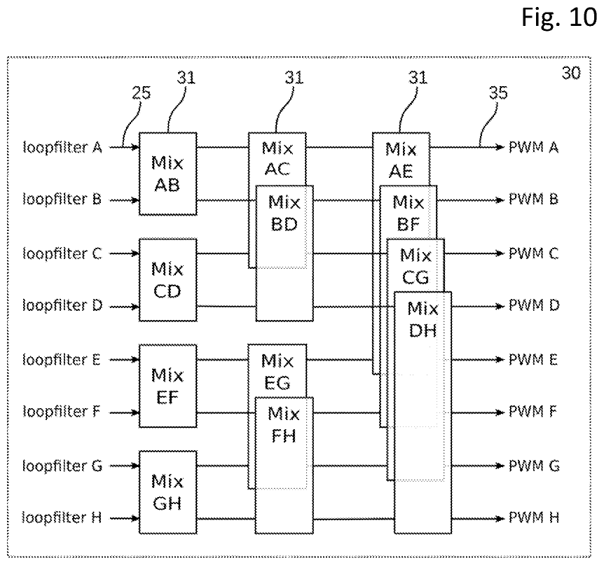

FIG. 10 shows an example of the loop-filter, butterfly mixers, PWMs and crossbar which can be placed after the network of μDSPs (also see FIG. 5)

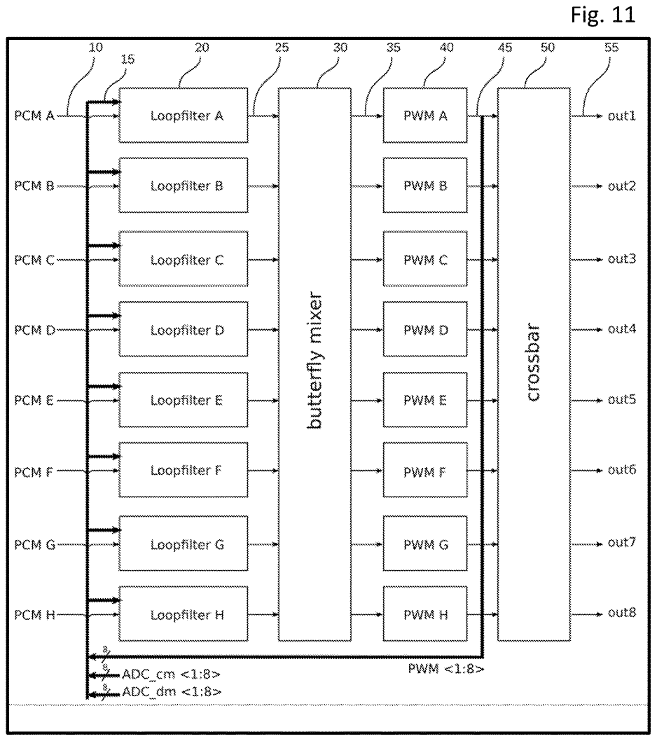

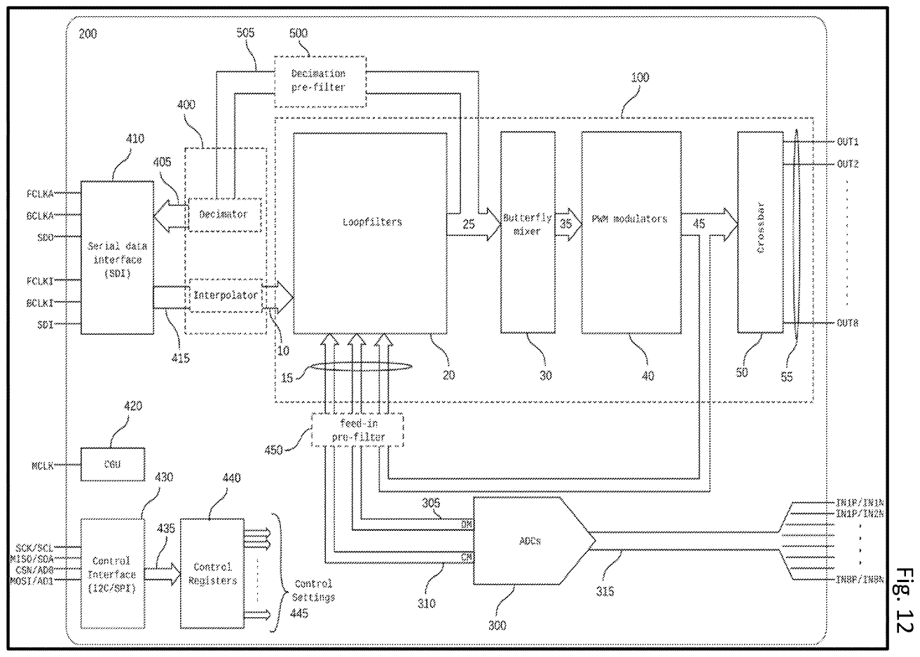

FIG. 11 shows a block-schematic of the butterfly mixers in more detail.

FIG. 12 shows an example of the use of the μDSPs (400) in an integrated circuit for control of audio signals, which also uses the loop-filters, butterfly mixers, PWM modulators and various other circuits. In the exemplary use in the figure, the μDSPs handle the interpolation of the incoming audio signals and the decimation of the loop-filter outputs.

1-17. (canceled)

18. A Digital Signal Processor (DSP) for streaming an audio application, comprising:
at least two micro digital signal processors (μDSPs) forming a network, wherein each individual μDSP comprises a local memory with a size <2¹⁸ words, and each individual word has a size not larger than 256 bits, wherein the at least two μDSPs are connected or connectable in series and/or in parallel, wherein the at least two micro digital signal processors (μDSPs) each individually is configured to receive an input signal, wherein the at least two micro digital signal processors (μDSPs) each individually comprises at least two μDSP data interface inputs, and wherein the at least two micro digital signal processors (μDSPs) each individually is configured to provide an output signal to a digital analogue converter, and wherein each micro digital signal processor is configured to operate at a clock frequency of >1 MHz.

19. The Digital Signal Processor for streaming an audio application according to claim 18, wherein each individual micro digital signal processor (μDSP) comprises a control interface configured to process an input from an external source such as a host processor, where this input is used to write or read contents of the program-memory (PMEM) and/or coefficient memory (YMEM) and thereby control a behaviour of the μDSP and/or read out status information.

20. The Digital Signal Processor (DSP) for streaming an audio application according to claim 18, wherein the at least two micro digital signal processors (μDSPs) each individually comprises at least two μDSP data interface outputs.

21. The Digital Signal Processor (DSP) for streaming an audio application according to claim 18, wherein the at least two μDSPs form a switchable network, wherein the network comprises an array n*m of μDSP routers_{(i,j)}, wherein i∈ and j∈, wherein n is in the range of 2-2⁸, wherein m is in the range of 2-2⁸, and wherein each individual router_{(i,j)} comprises data inputs and outputs for the μDSP and also comprises at least two router inputs and at least two router outputs for connecting to a router_{(i,j)} selected from a router_{(i+1,j)} a router_{(i,j+1)}, a router_{(i,j-1)}, and a router_{(i-1,j)}.

22. The Digital Signal Processor (DSP) for streaming an audio application according to claim 18, comprising at least one 32-bit μDSP 32-bit and at least one 96-bit μDSP.

23. The Digital Signal Processor (DSP) for streaming an audio application according to claim 22, wherein the at least one 96-bit μDSP comprises three 32-bit submemories.

24. The Digital Signal Processor (DSP) for streaming an audio application according to claim 18, wherein the at least two μDSPs or the network of the at least two μDSPs are/is configured to receive multiple inputs selected from a pulse width modulator input, a loop filter input, an Analog to Digital Converter (ADC) input, a LowLatency ADC (LLADC) input, bitstream inputs, a Micro Controller (MCU) input, a routing input, and a Serial Audio Port (SAP) input, and wherein the at least two μDSPs or the network of the at least two μDSPs are/is configured to provide multiple outputs selected from a pulse width modulator output, a loop filter output, an ADC output, a low-latency ADC output, a Direct Stream Digital output, a digital microphone output, an MCU output, a routing output, and a SAP output.

25. The Digital Signal Processor (DSP) for streaming an audio application according to claim 18, wherein the at least two μDSPs each individually is configured to mark a frame input with a unique identifier.

26. The Digital Signal Processor (DSP) for streaming an audio application according to claim 18, wherein the at least two μDSPs each individually is configured to be event driven, wherein the event is selected from an external event, or from an internal event.

27. The Digital Signal Processor (DSP) for streaming an audio application according to claim 18, wherein each individual μDSP is configured to process data over a data path, which is configured to be controlled by a program controller, wherein the controller is configured to receive an input from a local data register, to provide a mask over a received input, to rotate a masked input, to multiply a rotated input, to perform arithmetic operations on a rotated input and/or on the input from the local data register, to provide a flag on an arithmetic output, to provide a guard on the arithmetic output, to clip overflow, and to provide an output to the local data register.

28. The Digital Signal Processor (DSP) for streaming an audio application according to claim 18, wherein the at least two μDSPs each individually is configured to comprise in an accumulator one guard bit per eight word bits, wherein the guard bit is the first or the last bit of the eight bits of the word.

29. The Digital Signal Processor (DSP) for streaming an audio application according to claim 18, comprising at least one local latch-buffer store configured for performing a local loop, at least one local program counter (PCL) for driving a 32-bits output to a data register and for driving an output from a local address register, wherein the PCL is configured to drive an output to an n^{th} local address register and to drive an output from an n+I^{th} local address register, the at least one local latch-buffer store comprising four local address registers.

30. The Digital Signal Processor (DSP) for streaming an audio application according to claim 29, wherein the local latched buffer store is configured to receive a program data (PDATA), or a bundle of signals grouped in fields.

31. An audio reproduction signal path, comprising a Digital Signal Processor (DSP) for streaming an audio application, wherein the Digital Signal Processor comprises at least two micro digital signal processors (μDSPs) forming a network; and
wherein:
each individual μDSP comprises a local memory with a size <218 words, and each individual word has a size not larger than 256 bits;
the at least two μDSPs are connected or connectable in series and/or in parallel;
the at least two micro digital signal processors (μDSPs) each individually is configured to receive an input signal;
the at least two micro digital signal processors (μDSPs) each individually comprises at least two μDSP data interface inputs;
the at least two micro digital signal processors (μDSPs) each individually is configured to provide an output signal to a digital analogue converter; and
each micro digital signal processor is configured to operate at a clock frequency of >1 MHz.

32. The audio reproduction signal path according to claim 31, wherein the μDSPs are configured to provide an input to a programmable pulse width modulating (PWM) controller (100), where the DSPs are used for an interpolation of a PCM input signal, a decimation of a loop-filter output signal, an audio processing and filtering and/or adapting a behaviour of loop filters (20).

33. An integrated circuit, comprising a Digital Signal Processor (DSP) for streaming an audio application, wherein the Digital Signal Processor comprises at least two micro digital signal processors (μDSPs) forming a network; and wherein:
each individual μDSP comprises a local memory with a size <218 words, and each individual word has a size not larger than 256 bits;
the at least two μDSPs are connected or connectable in series and/or in parallel;
the at least two micro digital signal processors (μDSPs) each individually is configured to receive an input signal;
the at least two micro digital signal processors (μDSPs) each individually comprises at least two μDSP data interface inputs;
the at least two micro digital signal processors (μDSPs) each individually is configured to provide an output signal to a digital analogue converter; and
each micro digital signal processor is configured to operate at a clock frequency of >1 MHz.

34. An electronic device, comprising a Digital Signal Processor, wherein the Digital Signal Processor comprises at least two micro digital signal processors (μDSPs) forming a network; and wherein:
each individual μDSP comprises a local memory with a size <218 words, and each individual word has a size not larger than 256 bits;
the at least two μDSPs are connected or connectable in series and/or in parallel;
the at least two micro digital signal processors (μDSPs) each individually is configured to receive an input signal;
the at least two micro digital signal processors (μDSPs) each individually comprises at least two μDSP data interface inputs;
the at least two micro digital signal processors (μDSPs) each individually is configured to provide an output signal to a digital analogue converter; and
each micro digital signal processor is configured to operate at a clock frequency of >1 MHz.

35. The audio reproduction signal path according to claim 31, further comprising at least one element selected from a loop filter, a butterfly mixer, a pulse width modulator (PWM), an output crossbar, and an output channel; wherein:
the loop filter is configured to receive an input from at least one of the micro DSPs;
the butterfly mixer is configured to receive inputs from at least one loop filter, to mix the inputs from the at least one loop filter, and to provide an output to at least one PWM;
the PWM is configured to receive an input from the butterfly mixer, to pulse width modulate the output of the butterfly mixer, and to provide an output to the output crossbar or to the output channel.

36. The audio reproduction signal path according to claim 32, wherein the PWM controller comprises in series
(i) at least two parallel loop filters for loop-gain and signal processing, each loop filter comprising multiple inputs and at least one output, wherein the loop filter is adapted to receive PCM inputs from the DSP, to perform common mode control, differential mode control and LC compensation on the PCM signals, and the output of the loop filter is in electrical connection with (ii) at least one butterfly mixer, the butterfly mixer being capable of mixing at least two inputs and of providing at least two mixed outputs to (iii) at least two parallel pulse width modulators (PWMs); and wherein:
the loop filters, the butterfly mixer, and the PWMs are individually and independently programmable and adaptable, wherein the loop filter input is adapted to receive at least one of a local digital PWM processed output signal, and an ADC output.

37. The Digital Signal Processor (DSP) for streaming an audio application according to claim 26, wherein:
the external event is from a reset, an output request sample, an invalid frame, and a selection of a valid and normal frame event; and
the internal event is from a buffer full condition, from a buffer empty condition, or counter of event.
